(19) United States
(12) Patent Application Publication
(10) Pub. No.: US 2022/0077353 A1
(43) Pub. Date: Mar. 10, 2022

(54) LIGHT EMITTING DIODE PACKAGE HAVING A SMALL LIGHT EMITTING SURFACE

(71) Applicants: Tek Beng LOW, Melaka (MY); Chee Sheng LIM, Melaka (MY)

(72) Inventors: Tek Beng LOW, Melaka (MY); Chee Sheng LIM, Melaka (MY)

(21) Appl. No.: 17/013,939

(22) Filed: Sep. 8, 2020

(51) Int. Cl. H01L 33/48; H01L 33/50; H01L 33/62; H01L 23/00

(52) U.S. Cl. CPC H01L 33/486; H01L 33/50; H01L 2224/48996; H01L 24/48; H01L 2224/48245; H01L 33/62

(57) ABSTRACT

A light emitting diode package, including: a housing, wherein the housing includes a primary cavity, a primary cavity light emitting surface, and a secondary cavity, wherein the secondary cavity is positioned adjacent to the primary cavity; a lead frame associated with the housing; a light emitting diode light source, wherein the light emitting diode light source is associated with the primary cavity of the housing; an encapsulant filled into the primary cavity, wherein the encapsulant is associated with a light converting element; and wherein the ratio of the surface area of the primary cavity light emitting surface to that of the light emitting diode light source is less than 2.0.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A SEQUENCE LISTING

Not applicable.

### BACKGROUND OF THE INVENTION

### 1. Field of the Invention

The present invention relates in general to light emitting diode (LED) packages, and more particularly, to improved light emitting diode packages that include a small light emitting surface (LES), which improves color uniformity of the LED.

### 2. Background Art

By way of background, and as is shown collectively in prior art FIGS. 1-3, conventional LED package design 10 includes substrate 12 (e.g., metal alloy, PCB, ceramic, etcetera), housing 14 having cavity 16 and cavity opening 18. Cavity 16 is filled with transparent and/or translucent encapsulant 20. Housing 14 is normally made using a plastic and/or resin (natural and/or synthetic) material. Light emitting semiconductor element or chip 22 is traditionally located at the bottom of cavity 16 and attached to substrate 12. Electrically conductive wires 24 are used to connect semiconductor element or chip 22 to the terminals associated with first and second electrodes (e.g., anode and cathode) 26 and 28, respectively. As is best shown in FIG. 2, wires 24 are located within cavity 16.

In order to extract the light output, cavity 16 is conventionally made with a large opening in order to accommodate both LED chip 22 and wires 24. Notably, the cavity opening is far larger than the size of LED chip 22. The typical surface area ratio between the cavity opening and the LED chip is greater than 2.5. As is shown in FIG. 3, the light in a conventional LED gets reflected off of both the substrate base and the cavity wall.

In the case of a white LED, a light converting element, such as yellow phosphor, is added into encapsulant 20. When coupled with a blue LED chip light source 22, the converted polychromatic light and blue light will yield white light. However, due to the large cavity opening, the light conversion path is not uniform across the component. In particular, more light conversion will occur at areas away from the chip (See FIG. 3; conversion paths A and C) compared to the area above chip 22 (See FIG. 3; conversion path B). As a result, the color uniformity is less than desirable across the light emitting surface of the component.

The present invention discloses an improved light emitting diode package that includes a cavity having a small light emitting surface (LES), which improves color uniformity of the LED.

By way of additional background, LED packages and encapsulants associated with LED packages have been known in the art for years, and are the subject of a plurality of patents and publications, including: U.S. Pat. No. 9,559,275 entitled “Light Emitting Device Package and Light Unit Having the Same,” U.S. Pat. No. 8,564,005 entitled “Light-Emitting Device Package,” U.S. Pat. No. 8,394,675 entitled “Manufacturing Light Emitting Diode (LED) Packages,” U.S. Pat. No. 8,314,479 entitled “Leadframe Package with Recessed Cavity for LED,” U.S. Pat. No. 7,646,029 entitled “LED Package Methods and Systems,” U.S. Pat. No. 6,407,411 entitled “LED Lead Frame Assembly,” United States Patent Application Publication Number 2005/0179041 entitled “Illumination System with LEDs,” United States Patent Application Publication Number 2005/0006794 entitled “Silicone Rubber Composition, Light-Emitting Semiconductor Embedding/Protecting Material and Light-Emitting Semiconductor Device,” United States Patent Application Publication Number 2003/0116769 entitled “Light Emission Diode Package,” United States Patent Application Publication Number 2002/0180345 entitled “Package Structure Containing Two LEDs,” International Application Publication Number WO 2015/059258 entitled “LED Encapsulant,” International Application Publication Number WO 2009/082177 entitled “Light Emitting Diode Package,” and International Application Publication Number WO 2009/072786 entitled “LED Package and Method for Fabricating the Same”—all of which are hereby incorporated herein by reference in their entirety including all references cited therein.

U.S. Pat. No. 9,559,275 appears to disclose a light emitting device package. The light emitting device is a package body that includes a first recess which is provided with a bottom face and a plurality of inner walls surrounding the bottom face, the plurality of inner walls including a first inner wall and a second inner wall, which are opposing walls; a lead frame exposed at the bottom face of the package body, the lead frame including a bottom frame and a reflector exposed along one of the first inner wall and the second inner wall; a light emitting element provided on the lead frame; and a transparent material provided in the package body to cover the light emitting element. A material of the reflector is the same as a material of the bottom frame of the lead frame.

U.S. Pat. No. 8,564,005 appears to disclose a light-emitting device package including: a package main body including a cavity and a lead frame including a mounting portion disposed in the cavity and a plurality of terminal portions; a light-emitting device chip mounted on the mounting portion; a plurality of bonding wires for electrically connecting the plurality of terminal portions and the light-emitting device chip; a light-transmitting encapsulation layer filled in the cavity; and a light-transmitting cap member disposed in the cavity and blocking the encapsulation layer to contact the plurality of bonding wires.

U.S. Pat. No. 8,394,675 appears to disclose a method of manufacturing an LED package that includes mounting a large panel frame/substrate (LPF/S) having a substantially square shape to a ring. The LPF/S includes a plurality of die pads and a corresponding plurality of leads arranged in a matrix pattern. Each of the die pads includes a planar chip attach surface. An LED chip is attached to the planar chip attach surface of each of the die pads. An encapsulant material is applied overlaying the LED chips and at least a part of the LPF/S. Each die pad and corresponding leads are separated from the LPF/S to form individual LED packages. The steps of attaching the LED chips and applying the encapsulant material are performed while the LPF/S is mounted to the ring.

U.S. Pat. No. 8,314,479 appears to disclose an LED package that includes a die pad having a bottom surface, an upper surface and a centrally located recessed cavity. The recessed cavity has a chip attach surface between the bottom surface and upper surface and sidewalls that extend from the recessed chip attach surface to the upper surface. The package additionally has leads arranged on opposing sides of the die pad. The leads have a bottom surface that is coextensive with the bottom surface of the die pad and an upper surface coextensive with the upper surface of the die pad. An LED chip is attached to the chip attach surface. The package further includes a package body having an encapsulant which fills space between the die pad and leads forming a bottom encapsulant surface that is coextensive with the bottom surfaces of the die pad and leads.

U.S. Pat. No. 7,646,029 appears to disclose methods and systems for LED modules that include an LED die integrated in an LED package with a sub-mount that includes an electronic component for controlling the light emitted by the LED die. The electronic component integrated in the sub-mount may include drive hardware, a network interface, memory, a processor, a switch-mode power supply, a power facility, or another type of electronic component.

U.S. Pat. No. 6,407,411 appears to disclose an improved LED lead frame packaging assembly that includes a thermally conducting, electrically insulating material that enhances the thermal conduction and structural integrity of the assembly, a UV-resistant encapsulant material, and an integral ESD material that reduces electrostatic discharge. The thermally conducting, electrically insulating material creates an electrically insulating, thermally conductive path in the lead frame assembly for dissipation of power and also acts as a mounting structure thus allowing for the use of a soft encapsulant material, preferably a silicone.

United States Patent Application Publication Number 2005/0179041 appears to disclose a system that includes a light emitting diode (LED), such as a projection system, which may be increased by using an LED chip that has a light emitting surface that emits light directly into any medium with a refractive index of less than or equal to approximately 1.25. For example, the LED chip may emit light directly into the ambient environment, such as air or gas, instead of into an encapsulant. The low refractive index decreases the étendue of the LED, which increases luminance. Moreover, without an encapsulant, a collimating optical element, such as a lens, can be positioned close to the light emitting surface of the LED chip, which advantageously permits the capture of light emitted at large angles. A secondary collimating optical element may be used to assist in focusing the light on a target, such as a micro-display.

United States Patent Application Publication Number 2005/0006794 appears to disclose a silicone rubber composition, comprising: (A) an organopolysiloxane containing at least two aliphatic unsaturated bonds; (B) an organopolysiloxane of resin structure comprising SiO₂ units, R³ₙR⁴ₚSiO_{0.5} units and R³_{q}R⁴ᵣSiO_{0.5} units wherein R³ is vinyl or allyl, R⁴ is a monovalent hydrocarbon group free of aliphatic unsaturation, n is 2 or 3, p is 0 or 1, n+p=3, q is 0 or 1, r is 2 or 3, and q+r=3; (C) an organohydrogenpolysiloxane having at least two SiH groups; and (D) a platinum catalyst cures into a silicone rubber having excellent rubbery and strength properties and little surface tack.

United States Patent Application Publication Number 2003/0116769 appears to disclose an LED package, made of ceramic substrates and having a reflective metal plate. This LED package consists of a first ceramic substrate, which has a chip mounting area on its top surface, and is provided with a predetermined conductive pattern formed around the chip mounting area. One or more LED chips are seated on the chip mounting area of the first ceramic substrate, and are connected to the conductive pattern. A second ceramic substrate is mounted on the top surface of the first ceramic substrate and has a cavity at a position corresponding to the chip mounting area. The reflective metal plate is set in the cavity of the second ceramic substrate to surround the LED chips. This LED package effectively controls the luminous intensity of the LED chips and the angular distribution of the luminance. The reflective metal plate also collaterally acts as a heat sink effectively dissipating heat from the LED chips to the surroundings of the LED package.

United States Patent Application Publication Number 2002/0180345 appears to disclose a package structure containing two LEDs (light emitting diodes), which are packaged in cascade and capable of emitting lights with different wavelengths. For example, by packaging a yellow LED die above a blue LED die or packaging a blue LED die above a yellow LED die, a desaturated blue, desaturated yellow or white light can be obtained when a blue light is emitted through a yellow light or a yellow light is emitted through a blue light. The present invention can be a single-anode-single-cathode or a double-anode-single-cathode package structure, wherein the latter structure can continually change the emitted light in a certain range by adjusting input voltages of the anodes.

International Application Publication Number WO 2015/059258 appears to disclose an LED encapsulant comprising a scattering particle mixture, which includes: (i) a linear polymer including a dimethylsiloxane group which has a vinyl end substituent and/or a linear polymer including a methylphenylsiloxane group which has a vinyl end substituent; and (ii) at least one vinyl-based resin selected from the group consisting of a vinyl-based ViMQ resin.

International Application Publication Number WO 2009/082177 appears to disclose a light emitting diode (LED) package that includes a light emitting diode (LED) package that includes a pair of lead frames connected with at least one LED chip through a metal wire, a package body integrally fixed with the lead frames and having a cavity having an open top, a lead frame bent downwardly to a lower part of an external mounting surface of the package body, a light-transmissive, transparent resin covering the LED chip and filling the cavity, a recess formed in a bottom surface of the cavity, in which the LED chip is mounted, and a transparent resin including a fluorescent material formed in the recess and the cavity. Accordingly, the amount of light-transmissive, transparent resin filling the cavity is reduced to save on manufacturing costs, and the height of the resin is lowered to improve the luminance of light. Also, the height of the package body is lowered, contributing to manufacturing a small product.

International Application Publication Number WO 2009/072786 appears to disclose an LED package that comprises a base having an LED chip mounted thereon, an encapsulation member formed by a light-transmittable resin to encapsulate the LED chip, and a housing formed to expose a top portion of the encapsulation member and to encompass a side surface of the encapsulation member, wherein the encapsulation member is formed by a transfer molding process using a mold to have a predetermined shape. Further, the housing may be light-transmittable.

While the above-identified patents and publications do appear to disclose a plurality of LED package and cavity configurations, none of the above-identified patents and publications appear to disclose an improved light emitting diode package that includes a small LES, which improves color uniformity of the LED.

These and other objects of the present invention will become apparent in light of the present specification, claims, and drawings.

### SUMMARY OF THE INVENTION

The present invention is directed to a light emitting diode package comprising, consisting essentially of, and/or consisting of: (a) a housing, wherein the housing includes a primary cavity, a primary cavity light emitting surface, and a secondary cavity, wherein the secondary cavity is positioned adjacent to the primary cavity; (b) a lead frame associated with the housing; (c) a light emitting diode light source, wherein the light emitting diode light source is associated with the primary cavity of the housing; (d) an encapsulant filled into the primary cavity, wherein the encapsulant is associated with a light converting element; and (e) wherein the ratio of the surface area of the primary cavity light emitting surface to that of the light emitting diode light source is less than 2.0.

The present invention is also directed to a light emitting diode package comprising, consisting essentially of, and/or consisting of: (a) a housing, wherein the housing includes a primary cavity, a primary cavity light emitting surface, and a secondary cavity, wherein the secondary cavity is positioned adjacent to the primary cavity; (b) a lead frame associated with the housing; (c) a light emitting diode light source, wherein the light emitting diode light source is associated with the primary cavity of the housing; (d) an encapsulant filled into the primary cavity, wherein the encapsulant is associated with a light converting element; and (e) wherein a wire connection is made between the primary and secondary cavities via a wire channel to provide electrical connection between the light emitting diode light source and the lead frame.

The present invention is further directed to a light emitting diode package comprising, consisting essentially of, and/or consisting of: (a) a housing, wherein the housing includes a primary cavity, a primary cavity light emitting surface, a secondary cavity, wherein the secondary cavity is positioned adjacent to the primary cavity, and a tertiary cavity, wherein the tertiary cavity is positioned adjacent to the primary cavity; (b) a lead frame associated with the housing; (c) a light emitting diode light source, wherein the light emitting diode light source is associated with the primary cavity of the housing; (d) an encapsulant filled into the primary cavity, wherein the encapsulant is associated with a light converting element; and (e) wherein the ratio of the surface area of the primary cavity light emitting surface to that of the light emitting diode light source is less than 2.0.

The present invention is yet further directed to a light emitting diode package comprising, consisting essentially of, and/or consisting of: (a) a housing, wherein the housing includes a primary cavity, a primary cavity light emitting surface, a secondary cavity, wherein the secondary cavity is positioned adjacent to the primary cavity, and a tertiary cavity, wherein the tertiary cavity is positioned adjacent to the primary cavity; (b) a lead frame associated with the housing; (c) a light emitting diode light source, wherein the light emitting diode light source is associated with the primary cavity of the housing; (d) an encapsulant filled into the primary cavity, wherein the encapsulant is associated with a light converting element; and (e) wherein a wire connection is made between the primary and tertiary cavities via a wire channel to provide electrical connection between the light emitting diode light source and the lead frame.

### BRIEF DESCRIPTION OF THE DRAWINGS

Certain embodiments of the present invention are illustrated by the accompanying figures. It will be understood that the figures are not necessarily to scale and that details not necessary for an understanding of the invention or that render other details difficult to perceive may be omitted.

It will be further understood that the invention is not necessarily limited to the particular embodiments illustrated herein.

The invention will now be described with reference to the drawings wherein:

FIG. 1 is a top view of a prior art light emitting diode package;

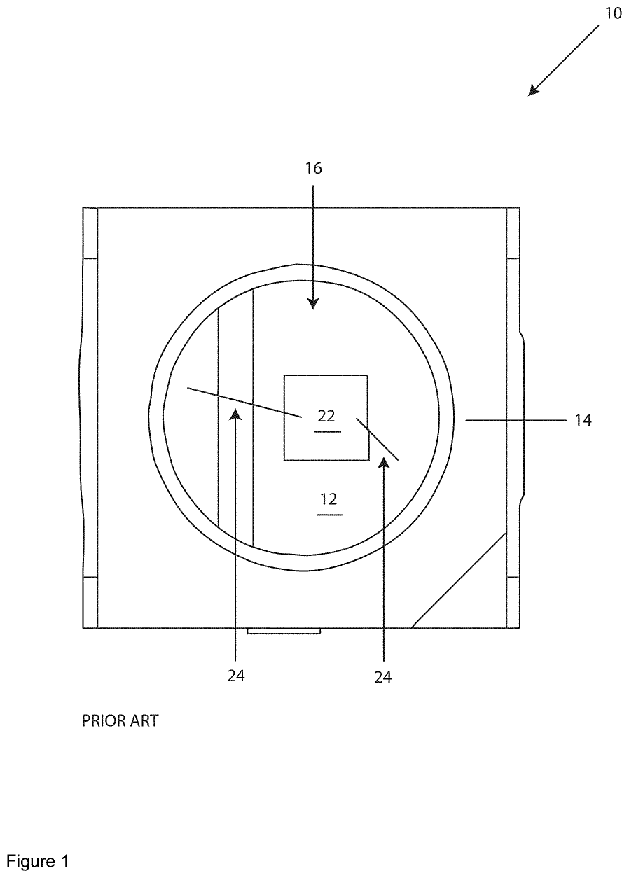

FIG. 2 is a cross-sectional view of a prior art light emitting diode package;

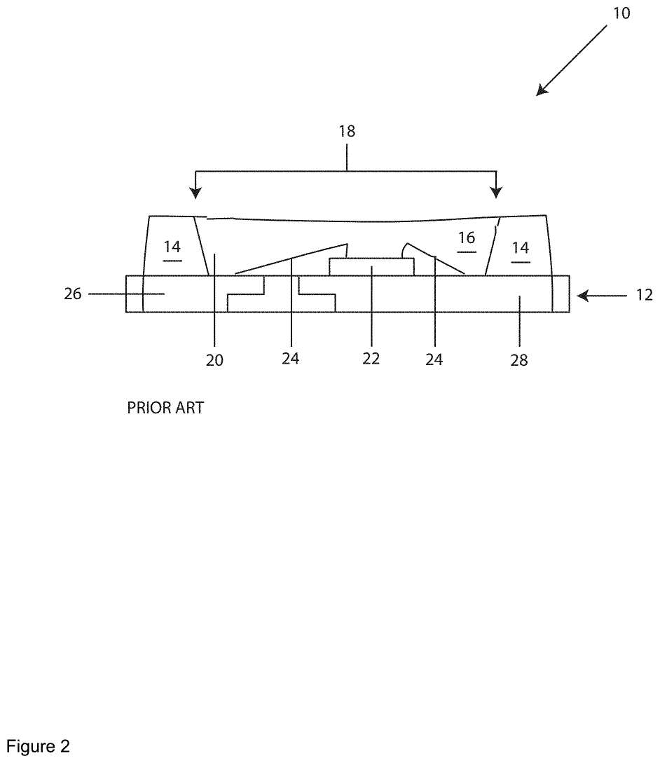

FIG. 3 is a cross-sectional view of a prior art light emitting diode package showing a plurality of conversion pathways which lead to less than desirable color uniformity;

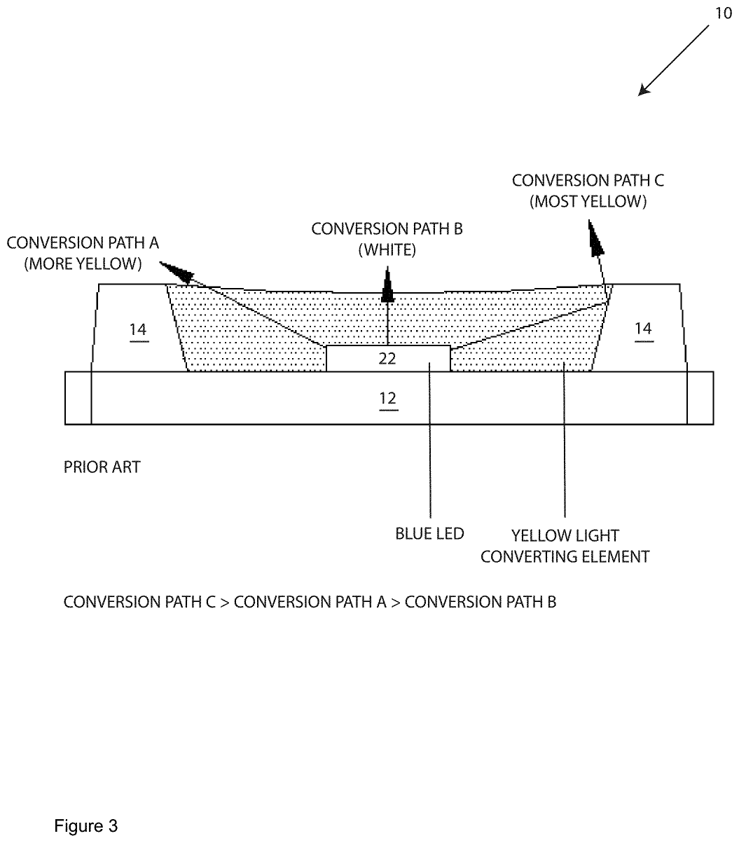

FIG. 4 is a top view of a first embodiment of a light emitting diode package manufactured in accordance with the present invention;

FIG. 5 is a cross-sectional view of a first embodiment of a light emitting diode package manufactured in accordance with the present invention;

FIG. 6 is a cross-sectional view of a first embodiment of a light emitting diode package manufactured in accordance with the present invention showing a plurality of substantially similar conversion pathways which lead to improved color uniformity;

FIG. 7 of the drawings is a two-dimensional Color Over Angle (CX) plot showing color change as a function of viewing angle from the central axis;

FIG. 8 is a top view of a second embodiment of a light emitting diode package manufactured in accordance with the present invention; and

FIG. 9 is a cross-sectional view of a second embodiment of a light emitting diode package manufactured in accordance with the present invention.

### DETAILED DESCRIPTION OF THE INVENTION

While this invention is susceptible of embodiment in many different forms, there is shown in the drawings and described herein in detail several specific embodiments with the understanding that the present disclosure is to be considered as an exemplification of the principles of the invention and is not intended to limit the invention to the embodiments illustrated.

It will be understood that like or analogous elements and/or components, referred to herein, may be identified throughout the drawings by like reference characters. In addition, it will be understood that the drawings are merely schematic representations of one or more embodiments of the invention, and some of the components may have been distorted from their actual scale for purposes of pictorial clarity.

As will be explained in greater detail hereinbelow, the present invention is directed to an improved light emitting diode package that includes a cavity having a small light emitting surface (LES), which improves color uniformity.

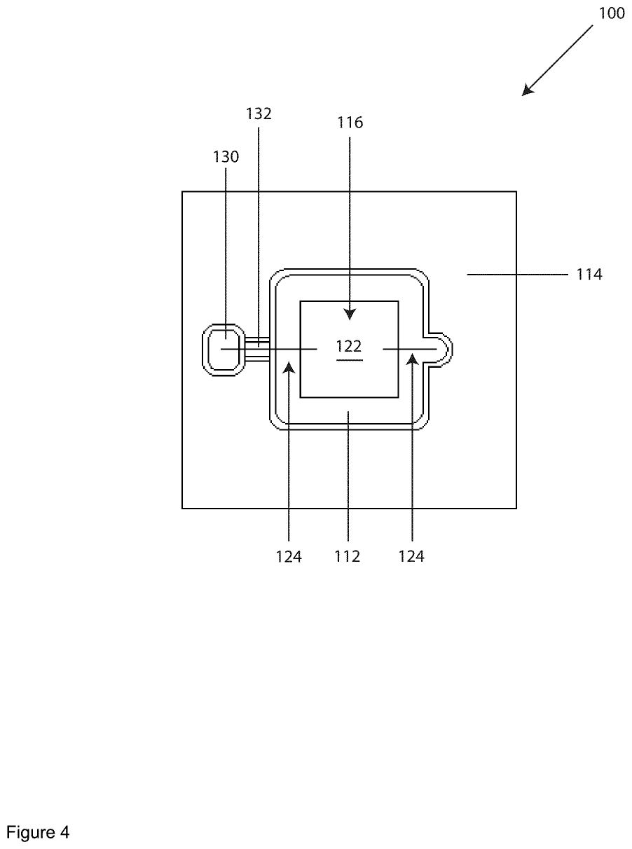

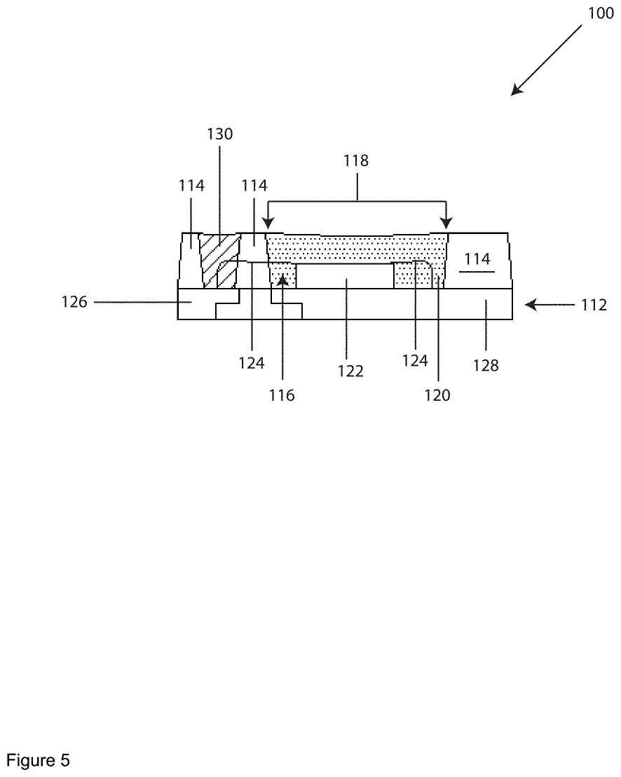

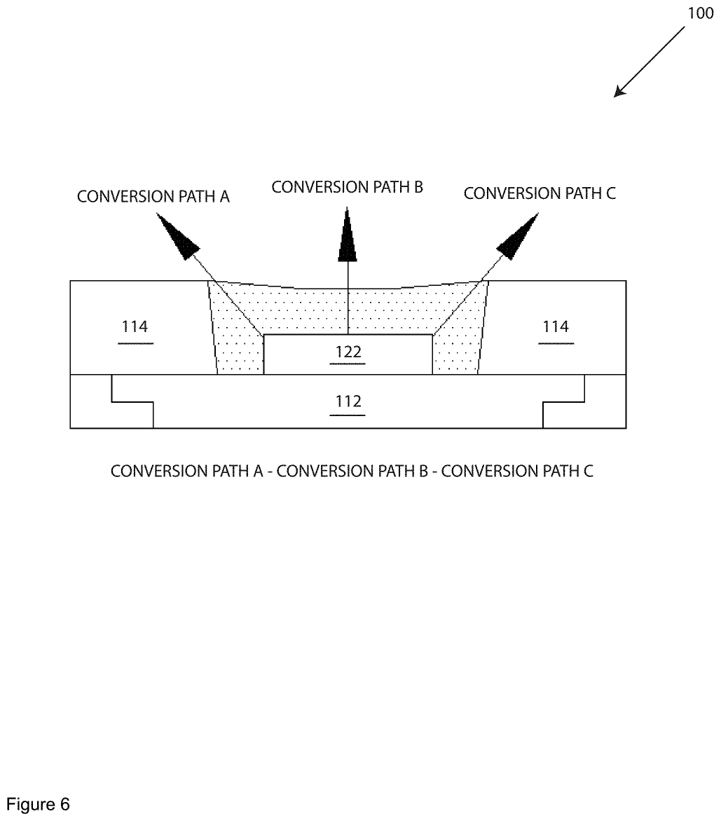

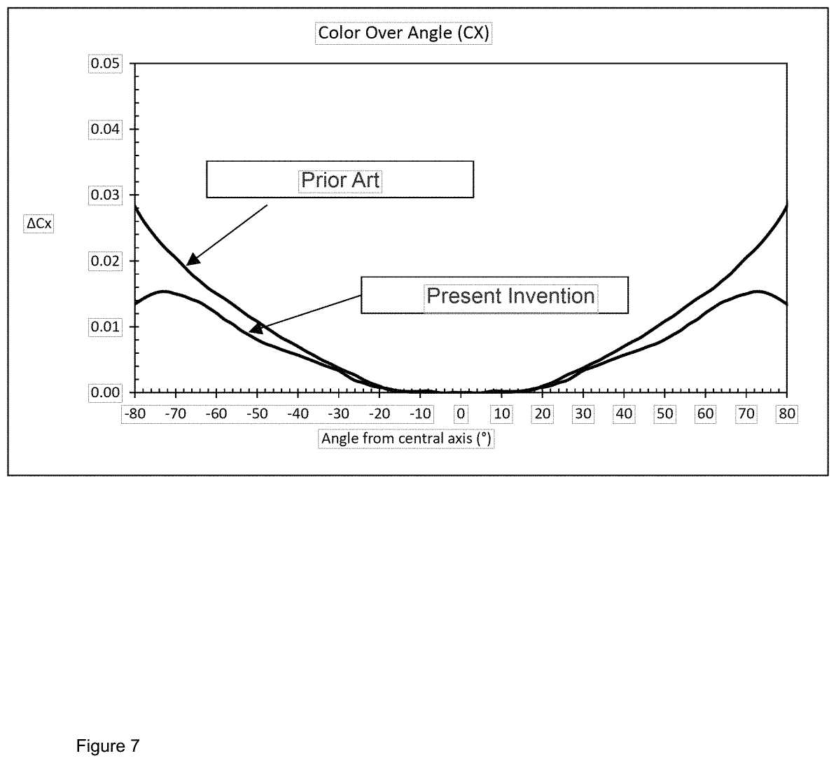

Referring collectively now to FIGS. 4-6 in a first embodiment of the present invention, light emitting diode package 100 of the present invention generally includes: substrate or frame 112 (e.g., metal alloy, PCB, ceramic, etcetera) associated with first electrode 126 (e.g., anode) and second electrode 128 (e.g., cathode); housing 114 having primary cavity 116 and primary cavity opening 118 filled with transparent and/or translucent encapsulant 120 (n.b., opening 118 becomes a small light emitting surface when filled with encapsulant 120); light emitting semiconductor element or chip 122; and secondary cavity 130 positioned adjacent to primary cavity 116. Secondary cavity 130 is filled with an opaque encapsulant. Wire channel 132 is positioned between primary cavity 116 and secondary cavity 130. Secondary cavity 130 accommodates wire 124 and enables primary cavity 116 to comprise a small light emitting surface so that the conversion pathways are essentially the same (See FIG. 6). When the conversion pathways are substantially similar, then the color uniformity of the light emitting diode package is substantially increased (See FIG. 7).

In a preferred embodiment of the present invention, the ratio of the surface area of primary cavity light emitting surface to that of the light emitting diode light source 122 is less than 2.0.

In another preferred embodiment of the present invention, the ratio of the surface area of primary cavity light emitting surface to the light emitting diode light source 122 ranges from 1.2 to 1.9.

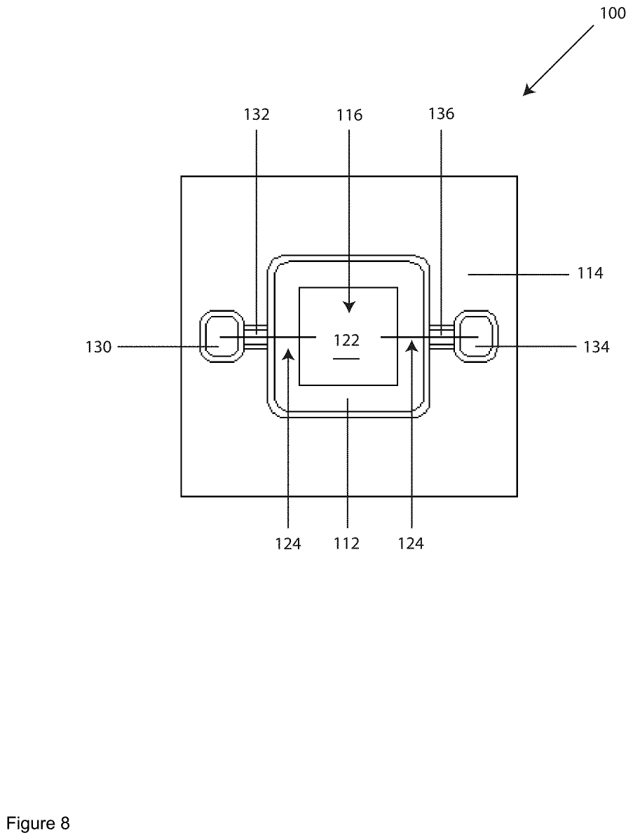

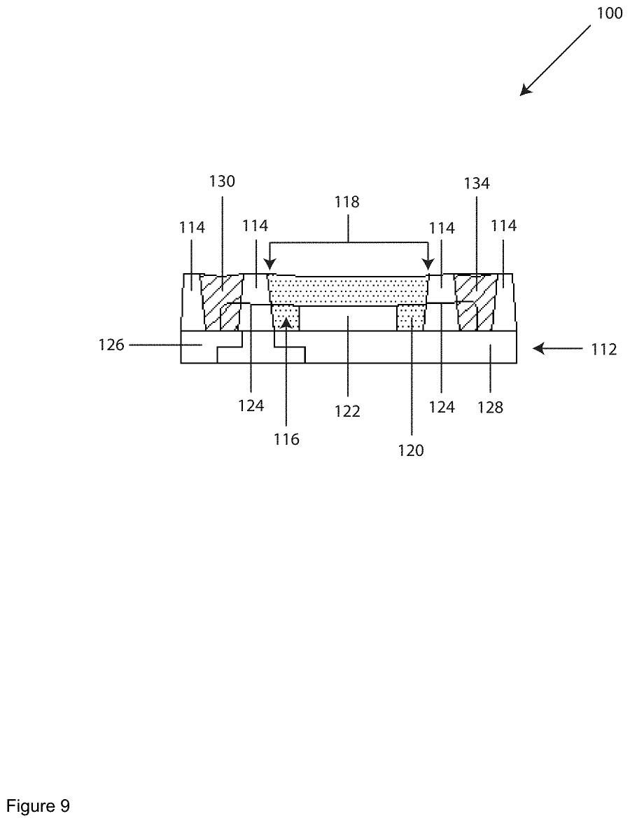

Referring collectively now to FIGS. 8-9 in a second embodiment of the present invention, light emitting diode package 100 of the present invention generally includes: substrate or frame 112 (e.g., metal alloy, PCB, ceramic, etcetera) associated with first electrode 126 (e.g., anode) and second electrode 128 (e.g., cathode); housing 114 having primary cavity 116 and primary cavity opening 118 filled with transparent and/or translucent encapsulant 120 (n.b., opening 118 becomes a small light emitting surface when filled with encapsulant 120); light emitting semiconductor element or chip 122; secondary cavity 130 positioned adjacent to primary cavity 116; and tertiary cavity 134 positioned adjacent to primary cavity 116. Secondary and tertiary cavities 130 and 134, respectively, are filled with an opaque encapsulant. Wire channel 132 is positioned between primary cavity 116 and secondary cavity 130, and additional wire channel 136 is positioned between primary cavity 116 and tertiary cavity 134. Secondary and tertiary cavities 130 and 134, respectively, accommodate wires 124 and further enable primary cavity 116 to comprise a small light emitting surface so that the conversion pathways are essentially the same (See FIG. 6).

The foregoing description merely explains and illustrates the invention and the invention is not limited thereto except insofar as the appended claims are so limited, as those skilled in the art who have the disclosure before them will be able to make modifications without departing from the scope of the invention.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etcetera shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology.

Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etcetera. As a non-limiting example, each range discussed herein can be readily broken down into a lower third, middle third and upper third, etcetera. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

What is claimed and desired to be secured by Letters Patent of the United States is:

1. A light emitting diode package, comprising:
a housing, wherein the housing includes a primary cavity, a primary cavity light emitting surface, and a secondary cavity, wherein the secondary cavity is positioned adjacent to the primary cavity;
a lead frame associated with the housing;
a light emitting diode light source, wherein the light emitting diode light source is associated with the primary cavity of the housing;
an encapsulant filled into the primary cavity, wherein the encapsulant is associated with a light converting element; and
wherein the ratio of the surface area of the primary cavity light emitting surface to that of the light emitting diode light source is less than 2.0.

2. A light emitting diode package, comprising:
a housing, wherein the housing includes a primary cavity, a primary cavity light emitting surface, and a secondary cavity, wherein the secondary cavity is positioned adjacent to the primary cavity;
a lead frame associated with the housing;
a light emitting diode light source, wherein the light emitting diode light source is associated with the primary cavity of the housing;
an encapsulant filled into the primary cavity, wherein the encapsulant is associated with a light converting element; and
wherein a wire connection is made between the primary and secondary cavities via a wire channel to provide electrical connection between the light emitting diode light source and the lead frame.

3. A light emitting diode package, comprising:
a housing, wherein the housing includes a primary cavity, a primary cavity light emitting surface, a secondary cavity, wherein the secondary cavity is positioned adjacent to the primary cavity, and a tertiary cavity, wherein the tertiary cavity is positioned adjacent to the primary cavity;
a lead frame associated with the housing;
a light emitting diode light source, wherein the light emitting diode light source is associated with the primary cavity of the housing;
an encapsulant filled into the primary cavity, wherein the encapsulant is associated with a light converting element; and
wherein the ratio of the surface area of the primary cavity light emitting surface to that of the light emitting diode light source is less than 2.0.

4. A light emitting diode package, comprising:
a housing, wherein the housing includes a primary cavity, a primary cavity light emitting surface, a secondary cavity, wherein the secondary cavity is positioned adjacent to the primary cavity, and a tertiary cavity, wherein the tertiary cavity is positioned adjacent to the primary cavity;
a lead frame associated with the housing;
a light emitting diode light source, wherein the light emitting diode light source is associated with the primary cavity of the housing;
an encapsulant filled into the primary cavity, wherein the encapsulant is associated with a light converting element; and
wherein a wire connection is made between the primary and tertiary cavities via a wire channel to provide electrical connection between the light emitting diode light source and the lead frame.

5. A light emitting diode package, comprising:
a housing, wherein the housing includes a primary cavity and a primary cavity light emitting surface;
a lead frame associated with the housing;
a light emitting diode light source, wherein the light emitting diode light source is associated with the primary cavity of the housing;
an encapsulant filled into the primary cavity, wherein the encapsulant is associated with a light converting element; and
means for improving color uniformity of the light emitting diode package.

6. The light emitting diode package according to claim 5, wherein the color uniformity improving means comprises a small primary cavity light emitting surface relative to cavity openings of conventional LED packages.

7. The light emitting diode package according to claim 6, wherein the ratio of the surface area of the primary cavity light emitting surface to that of the light emitting diode light source is less than 2.0.

8. The light emitting diode package according to claim 7, wherein the ratio of the surface area of the primary cavity light emitting surface to that of the light emitting diode light source ranges from 1.2 to 1.9.

9. The light emitting diode package according to claim 5, wherein the encapsulant is translucent and/or transparent.

10. The light emitting diode package according to claim 5, further comprising a secondary cavity positioned adjacent to the primary cavity.

11. The light emitting diode package according to claim 10, wherein the secondary cavity is at least partially filled with an opaque encapsulant.

12. The light emitting diode package according to claim 10, further comprising a wire channel positioned between the primary cavity and the secondary cavity.

13. The light emitting diode package according to claim 10, further comprising a tertiary cavity positioned adjacent to the primary cavity.

14. The light emitting diode package according to claim 13, wherein the tertiary cavity is at least partially filled with an opaque encapsulant.

15. The light emitting diode package according to claim 13, further comprising a wire channel positioned between the primary cavity and the tertiary cavity.
